(19) United States
(12) Patent Application Publication
(10) Pub. No.: US 2004/0212078 A1
(43) Pub. Date: Oct. 28, 2004

(54) Package structure and sensor module using the same

(75) Inventors: Hyeung-Gyu Lee, Seoul (KR); Youn-Seob Lee, Kyonggi-do (KR); Kyun Sunwoo, Kyonggi-do (KR); In-Soo Jeon, Seoul (KR)

Correspondence Address: McDERMOTT, WILL & EMERY, 600 13th Street, N.W., Washington, DC, 20005-3096, US

(73) Assignee: SMATTECH, INC.

(21) Appl. No.: 10/704,637

(22) Filed: Nov. 12, 2003

(30) Foreign Application Priority Data
Apr. 28, 2003 (KR) 10-2003-0026772

(51) Int. Cl. H01L 23/06

(52) U.S. Cl. 257/703

(57) ABSTRACT

The present invention relates to a package structure which is formed by coupling a sintered ceramic base substrate to a ceramic frame, and a sensor module using the package structure. The package structure comprises a frame made of ceramic or plastic material, a groove being formed at an end portion of the frame on the sintered ceramic substrate side; one or more sintered ceramic substrates provided with electrodes; and a bonding means made of glass material or organic bonding material, for bonding the sintered ceramic substrate and the frame.

### FIELD OF THE INVENTION

The present invention relates to a package structure and a sensor module using the package structure, and more specifically to a package structure formed by coupling a sintered ceramic base substrate to a ceramic frame, which is produced using a press mold method, and a sensor module using the package structure.

In the present invention, it is intended to reduce the production cost by using a new package structure, which is capable of eliminating lots of error factors while maintaining the advantages in the conventional multi layer package, without use of an expensive transparent glass member for a sensor module.

### BACKGROUND OF THE INVENTION

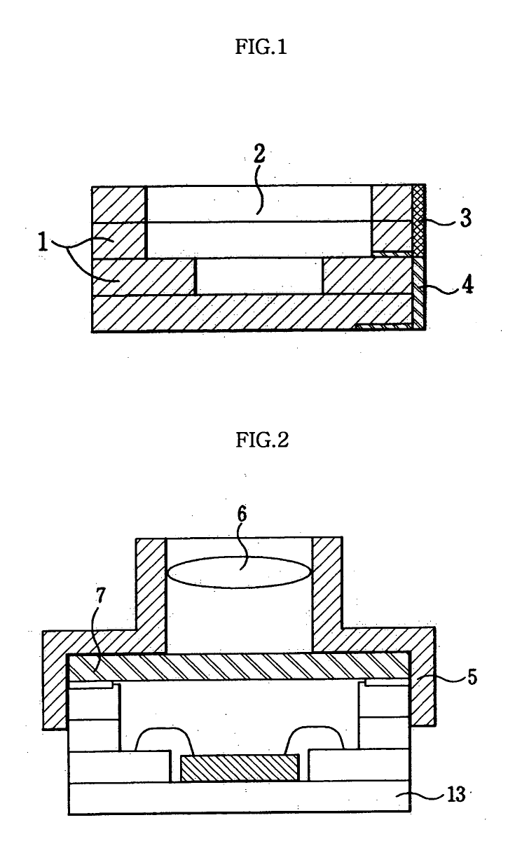

The conventional multi layer package (MLP) has two or more layers. Processes of manufacturing a cavity 2, a notch 3, a pattern print 4 or the like are performed to each layer as shown in FIG. 1. Sheets 1 subjected to the processes are stacked and sintered to product the multi layer package.

The package structure for a sensor such as a conventional CMOS image sensor which is also a multi layer package structure has problems of high production cost and many error factors.

In addition, in the package structure for a sensor, there is a problem that an electrical characteristic thereof is deteriorated by using a conductor having a low electrical conductance, such as tungsten (W) or molybdenum (Mo).

Furthermore, in the conventional multi layer package, there are problems that the production cost can be increased due to the various error factors, material loss can be generated when the cavity and the notch or the like are formed, and the production cost is increased due to use of very expensive production apparatuses such as a sheet former, a printer, a high-speed puncher or the like.

In addition, there are other problems that gas of H₂/N₂ or the like used in the concurrent sintering process is very expansive, and operators capable of managing each process for manufacturing the multi layer package are required as many as the number of the processes.

In addition, there is another problem that expensive molds for each of the layers are required to mass-produce the multi layer package.

Furthermore, there is another problem that the conventional multi layer package inherently has many error factors such as misalignment and delamination in the multi layer forming process, and fine particles attached to the multi layer package. Now, the problem mentioned above is will be described in more detail. In the case of processing the respective layer shapes to form the multi layer, the misalignment may be generated. At that time, the misalignment may result in deforming the shape of a side surface of a product, whereby the dimension precision can be decreased. Furthermore, in the case of laminating each of the layers, the delamination may be easily generated because the layers are not completely bonded each other, whereby the layers can not be closely bonded.

In addition, there is still another problem that when a green sheet having a flexible viscosity is blanked using a mold, the residues of the green sheet may be generated. At that time, the residues may be sometimes dropped and attached to a surface or the inside of the package under the laminating processes, whereby the residues can result in failure.

In addition, there is still another problem that since each density may be varied every portion in the laminating process, the camber can be generated after the sintering process.

On the other hand, when the sensor module is manufactured by use of the conventional multi layer package structure, a chip is mounted on a substrate 13 comprising the processed sheets 1 as shown in FIG. 2, and then a highly transparent glass 7 is installed over the sheets 1 by use of the organic material. A lens housing 5 equipped with a lens 6 is provided on the highly transparent glass 7.

The highly transparent glass 7 serves for hermetically sealing the chip. In this case, since the cost of the highly transparent glass 7 being used as the sealing means is very high, there is a problem of increase in the production cost of the sensor module.

### SUMMARY OF THE INVENTION

It is an object of the present invention to provide a package structure capable of reducing the number of processes thereof by forming a ceramic frame and a sintered ceramic base substrate by use of a mold method at one time and then sintering them, and a sensor module using the package structure.

Furthermore, it is another object of the present invention to provide a package structure capable of improving the structure of a sensor module by manufacturing the sensor module with use of the ceramic package produced by a press mold method without using the high cost transparent glass, and a sensor module using the package structure.

In order to accomplish the aforementioned objects of the present invention, an aspect of the present invention provides a package structure comprising, a frame, made of ceramic or plastic material, a groove being formed at an end portion of the frame on a sintered ceramic substrate side; one or more sintered ceramic substrates provided with electrodes; and a bonding means made of a glass or organic bonding material, for bonding the frame and the sintered ceramic substrate.

Furthermore, in the package structure according to the present invention, the frame made of the ceramic or plastic material is formed by a method of dry-pressing a powder and then sintering that, thereby the object mentioned above being accomplished.

Furthermore, in the package structure according to the present invention, the sintered ceramic substrate is formed by printing a metallic paste to a sheet and concurrently sintering the printed metallic paste, thereby the object mentioned above being accomplished.

Furthermore, in the package structure according the present invention, the sintered ceramic substrate is formed by sintering the ceramics, printing the metallic paste, and metallizing the printed metallic paste, thereby the object mentioned above being accomplished.

Furthermore, in the package structure according the present invention, the metallic paste is made of any one of tungsten (W), molybdenum (Mo), silver (Ag) and copper (Cu), thereby the object mentioned above being accomplished.

Furthermore, another aspect of the present invention provides a sensor module using a package structure, comprising: one or more sintered ceramic substrates provided with electrodes; a frame made of ceramic or plastic material, a groove being formed at an end portion of the frame on the sintered ceramic substrate side; a lens housing in which a projection is formed at a side end portion, the projection being inserted into the groove so that the lens housing is fixed to the frame; and an organic solvent or glass bonding material filled in the groove, hermetically sealing the lens housing, thereby the object mentioned above being accomplished.

Furthermore, in the sensor module using a package structure according to the present invention, the frame is formed to have a groove by a method of dry-pressing a powder and then sintering that, thereby the object mentioned above being accomplished.

Furthermore, in the sensor module using a package structure according to the present invention, the lens housing equipped with a lens is made of metal or plastic material, thereby the object mentioned above being accomplished.

Furthermore, in the sensor module using a package structure according to the present invention, the organic solvent and glass bonding material is an organic or hyaline bonding material, thereby the object mentioned above being accomplished.

### BRIEF DESCRIPTION OF THE DRAWINS

The above and other objects, advantages and features of the present invention will become apparent from the following description of preferred embodiments given in conjunction with the accompanying drawings, in which:

FIG. 1 is a view showing a conventional multi layer package structure,

FIG. 2 is a view showing a sensor module using the conventional multi layer package structure,

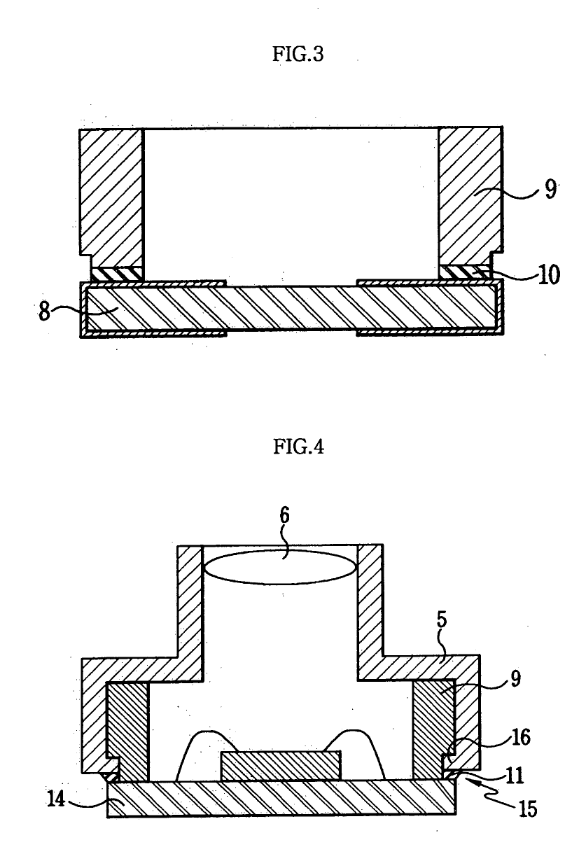

FIG. 3 is a view showing a package structure according to the present invention, and

FIG. 4 is a view showing a sensor module using the package structure according to the present invention.

### DETAILED DESCRIPTION OF THE PREFERRED EMBODIMENTS

Now, preferred embodiments of the present invention will be described in details with reference to the accompanying drawings.

Referring to FIG. 3, in the package structure according to the present invention, a base substrate 8 is constructed to have one or more sintered ceramic substrates which are formed by printing a metallic paste on a sheet and sintering them or sintering a ceramic, printing a metallic paste on the sintered ceramic, and metalizing them. At that time, the metallic paste is made of any one of tungsten (W), molybdenum (Mo), silver (Ag), and copper (Cu).

Furthermore, a frame 9 made of ceramic or plastic material and having a groove structure is laminated on the base substrate 8, the frame being formed by dry-pressing powders and sintering them.

In addition, the base substrate 8 is bonded to the frame 9 made of ceramic or plastic material by use of a glass or epoxy material.

On the other hand, when the sensor module is manufactured by use of the package structure according to the present invention, the sensor module is assembled with the one or more sintered ceramic substrates 14 provided with electrodes as shown in FIG. 4.

In addition, the frame 9 is made of ceramic or plastic material and is provided on a top surface of the sintered ceramic substrate 14, a groove 15 being formed at an end portion of the frame on the sintered ceramic substrate 14 side. A projection 16 protrudes from the side end of the lens housing 5. A projection 16 of the lens housing 5 is coupled with the groove 15 so that the lens housing 5 is fixed to the frame 9.

Next, the groove coupled with the projection 16 is filled with organic solvent or glass adhesive and then sealed with organic or glass sealing material 11. Therefore, the chip can be hermetically sealed without using the conventional highly transparent glass window.

According to the present invention, it is advantageous that it is possible to minimize a misalignment by relatively reducing the number of layers to be laminated in comparison with the conventional multi layer package structure, and to reduce the generation of particles because the notch hole blanking process is performed only to one layer without a cavity blanking process.

In addition, it is possible to increase the dimension precision in comparison with the conventional laminating process having a low dimension precision due to the different shrink rates of the layers, the misalignment, and the burrs generated in blanking.

Furthermore, it is possible to reduce the print failure every layer in comparison with the conventional multi layer package manufacturing method because the notch hole portion is formed only on one layer by a print process in the present invention.

Furthermore, there is a constructional problem in the conventional multi layer package that the highly transparent glass window of high cost must be first inserted between the multi layer package and the lens housing since the multi layer package can not be directly sealed with the lens housing. On the contrary, according to the present invention, since the package is made of ceramic in the form of one frame structure instead of the multi layer structure and the lens housing is also made of ceramic in the form of one frame structure, it is advantageous that the ceramic package and the ceramic lens hosing can be directly coupled by means of the groove and the projection formed at the end thereof, respectively, without using the high transparent glass window of high cost, and can be sealed with an adhesive material. Therefore, it is possible to reduce the production cost in the package process without use of the highly cost transparent glass member of high cost.

What is claimed is:

1. A package structure comprising:
one or more sintered ceramic substrates provided with electrodes;
a frame made of ceramic or plastic material, a groove being formed at a an end portion of the frame on the sintered ceramic substrate side; and
a bonding means made of a glass material or an organic bonding material, for bonding the frame and the sintered ceramic substrate.

2. A package structure according to claim 1, wherein the frame is formed by dry-pressing and sintering a powder.

3. A package structure according to claim 1, wherein the sintered ceramic substrate is formed by printing a metallic paste on a sheet and concurrently sintering the printed metallic paste.

4. A package structure according to claim 1, wherein the sintered ceramic substrate is formed by sintering ceramics, printing a metallic paste, and metallizing the printed metallic paste.

5. A package structure according to claim 3 or 4, wherein the metallic paste is made of any one of tungsten (W), molybdenum (Mo), silver (Ag) and copper (Cu).

6. A sensor module using a package structure, comprising:
one or more sintered ceramic substrates provided with electrodes;
a frame made of ceramic or plastic material, a groove being formed at an end portion of the frame on the sintered ceramic substrate side;
a lens housing of which a projection is formed at a side end portion, the projection being inserted into the groove so that the lens housing is fixed to the frame; and
an organic solvent or glass bonding material filled in the groove, for hermetically sealing the lens housing.

7. A sensor module using a package structure according to claim 6, wherein the frame is formed by dry-pressing and sintering a powder.

8. A sensor module using a package structure according to claim 6, wherein the lens housing equipped with a lens is made of a metal or plastic material.

9. A sensor module using a package structure according to claim 6, wherein the organic solvent or glass bonding material is an organic or hyaline bonding material.
